(19) United States
(12) Patent Application Publication
(10) Pub. No.: US 2005/0011673 A1
(43) Pub. Date: Jan. 20, 2005

(54) Methods for producing air bridges

(76) Inventors: Marvin Glenn Wong, Woodland Park, CO (US); John F. Casey, Colorado Springs, CO (US); Ling Liu, Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/620,127

(22) Filed: Jul. 15, 2003

(51) Int. Cl. H05K 1/11; H05K 3/40

(52) U.S. Cl. 174/261

(57) ABSTRACT

Methods for producing air bridges are disclosed. In one embodiment, an air bridge is produced by depositing one or more circuit components on a substrate, depositing a sacrificial material over at least a portion of the circuit components, depositing a first circuit trace over the sacrificial material, the first circuit trace crossing over the circuit components, and thermally decomposing the sacrificial material.

### BACKGROUND OF THE INVENTION

Crossovers in circuitry are sometimes needed for the proper routing of circuitry components. In some applications, the circuitry may be routed onto different substrate layers using vias to transition between layers. This may not be a suitable solution for other applications (e.g., high frequency applications) because of the sharp changes in signal directions and/or because the capacitance generated between circuit components separated by a layer of dielectric can be unacceptably high.

Another approach that may be suitable for high frequency applications has been to use an air bridge as a crossover. Air bridges have been created using dissolution or etching to remove sacrificial material used to produce the air bridge. Dissolution, or wet etching, may cause the air bridges to collapse by the surface tension of the solution. Additionally, agitation used in wet etching may cause the air bridges to be damaged or collapse by mechanical disturbance. Dry etching may be overly time consuming.

### SUMMARY OF THE INVENTION

Methods for producing air bridges are disclosed. In one embodiment, an air bridge is produced by depositing one or more circuit components on a substrate. A sacrificial material is deposited over at least a portion of the circuit components. A first circuit trace is then deposited over the sacrificial material so that it crosses over the circuit components. The sacrificial material is then thermally decomposed.

### BRIEF DESCRIPTION OF THE DRAWINGS

Illustrative embodiments of the invention are illustrated in the drawings in which:

FIG. 1 illustrates an exemplary plan view of a circuit crossover that uses a sacrificial material to produce an air bridge for the crossover;

FIG. 2 illustrates an elevation of the air bridge shown in FIG. 1 before the sacrificial material has been removed;

FIG. 3 illustrates the air bridge shown in FIGS. 1 and 2 after the sacrificial material has been removed;

FIG. 4 illustrates an exemplary method that may be used to produce the air bridge of FIG. 3;

FIG. 5 illustrates an elevation of a second exemplary embodiment of a circuit crossover that uses a sacrificial material to produce an air bridge for the crossover; and

FIG. 6 illustrates the air bridge of FIG. 5 after the sacrificial material has been removed;

### DETAILED DESCRIPTION

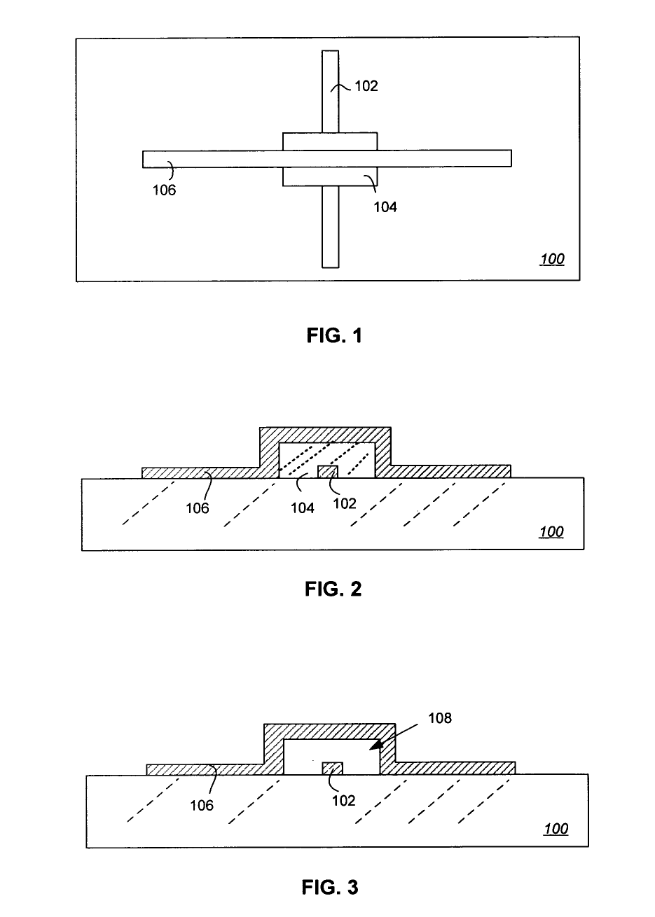

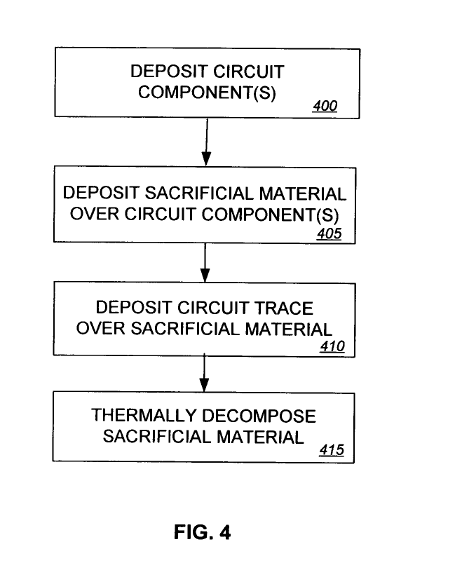

An exemplary embodiment of a circuit crossover using an air bridge for the crossover is illustrated in FIGS. 1-3. As illustrated in FIG. 4, the air bridge 108 may be produced by first depositing 400 one or more circuit components on a substrate 100. In FIG. 1, the one or more circuit components comprise a circuit trace 102. Circuit trace 102 may be a signal trace, a ground trace, a power trace, or other type of circuit trace. It should be appreciated that in alternate embodiments, the one or more circuit components may comprise circuit components other than or in addition to circuit trace 102, such as additional circuit traces, resistors, capacitors, or other active and passive circuit components.

Next, a sacrificial material 104 is deposited 405 over at least a portion of the circuit components 102. In one embodiment, the sacrificial material 104 may be deposited by spin coating the sacrificial material 104 over the circuit components 102. A mask layer (e.g., aluminum or silicon nitride) may then be deposited on the sacrificial material 104. Then a photoresist material may be spin-coated and patterned on the mask layer to a desired length and/or width of the air bridge 108. A portion of the mask layer not layered by the photoresist material may be etched away to pattern the mask layer and the photoresist material may then be removed. Next, reactive ion etching (or other process) may be used to remove the sacrificial material not layered by the mask layer. Finally, the mask layer may be etched away. It should be appreciated that in alternate embodiments, other methods may be used to deposit the sacrificial material 104 so that it is a desired length and/or width of the air bridge 108.

After the sacrificial material 104 has been deposited 405, a crossover circuit trace 106 is deposited over the sacrificial material 104 so that is crosses over the one or more circuit components 102. The crossover circuit trace 106 may be a signal trace, a power trace, a ground trace, or other type of circuit trace.

In one embodiment, the crossover circuit trace 106 may be deposited by depositing a conductive material and patterning the conductive material. By way of example, the conductive material may be patterned by depositing a photoresist material on the conductive material, patterning the photoresist material to a desired length and/or width, etching the conductive material not layered by the photoresist material, and removing the photoresist material. Before the conductive material is patterned, a protective material (e.g., photoresist material) may be deposited over the one or more circuit components 102 to protect the components from the patterning process. The crossover circuit trace 106 may also be deposited by depositing a photoresist material over the sacrificial material, patterning the photoresist material to have at least one opening of a desired length of the crossover circuit trace, depositing conductive material on the photoresist material and the opening, and removing the photoresist material along with the conductive material. It should be appreciated that methods other than that described above may also be used to deposit and/or pattern crossover circuit trace 106.

After the crossover circuit trace 106 has been deposited 410, the sacrificial material 104 is thermally decomposed 415. The sacrificial material 104 comprises a material that decomposes at a lower temperature than the material used for the circuit components 102 and the crossover circuit trace 106. By way of example, the sacrificial material 104 may be polynorbornene and may be decomposed at 425° Celsius at oxygen concentrations below 5 parts per million (ppm). Other suitable materials and temperatures may be used to thermally decompose sacrificial material 104. As illustrated in FIG. 3, the removal of the sacrificial material 104 produces an air bridge 108 for the crossover circuit trace 106 to crossover the one or more circuit components 102.

In one embodiment, air bridge 108 may be used in a high frequency application. It should be appreciated that thermal decomposition may provide a more stable structure for air bridge 108 than an air bridge produced by wet chemical removal, which may cause the air bridge to collapse by the surface tension of the solution. Unlike wet chemical removal, thermal decomposition may cause less damage or none at all to the substrate or components residing on the substrate.

Because air has a very low dielectric constant, the crossover capacitance generated between circuit components 102, 106 is low. Additionally, the vertical height of the air bridge (e.g., less than 5 mils) may be shorter than the vertical height of a conductive via (generally 20 mils or longer). Thus, the air bridge, unlike a conductive via, may be suitable in a high-frequency application because it may not create a sharp change in signal direction as the parts of the signal path may be shorter than the wavelength of the signal.

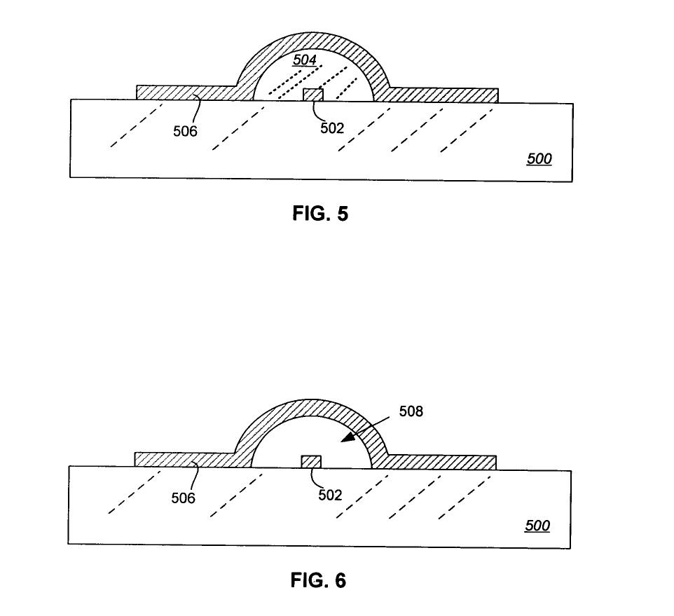

As illustrated in FIGS. 5 and 6, in some embodiments the air bridge 508 may be created in a dome shape to further reduce the angles of the signal path. The dome shaped air bridge 508 may be created by depositing one or more circuit components 502 on a substrate 500. Sacrificial material 504 (e.g., polynorbornene) is deposited over circuit components 502 in a manner causing the sacrificial material 504 to be dome shaped. By way of example, the sacrificial material may be deposited in multiple layers with each layer patterned shorter than the previous layer. The crossover circuit trace 506 is deposited over the sacrificial material 504. Finally, the sacrificial material 504 is thermally decomposed to produce air bridge 508. It should be appreciated that in alternate embodiments, the air bridge 508 may comprise shapes other than that depicted in FIG. 6.

While illustrative and presently preferred embodiments of the invention have been described in detail herein, it is to be understood that the inventive concepts may be otherwise variously embodied and employed, and that the appended claims are intended to be construed to include such variations, except as limited by the prior art.

1. An air bridge produced by:
depositing one or more circuit components on a substrate;
depositing a sacrificial material over at least a portion of the circuit components;
depositing a crossover circuit trace of uniform composition over the sacrificial material, the crossover circuit trace crossing over the circuit components; and
thermally decomposing the sacrificial material.

2. The air bridge of claim 1, wherein depositing a sacrificial material comprises depositing the sacrificial material In a manner causing the sacrificial material to be dome shaped.

3. The air bridge of claim 1, wherein the sacrificial material comprises polynorbornene.

4. The air bridge of claim 1, wherein the one or more circuit components comprise a circuit trace.

5. The air bridge of claim 4, wherein the circuit trace comprises a signal trace.

6. The air bridge of claim 4, wherein the circuit trace comprises a ground trace.

7. The air bridge of claim 4, wherein the circuit trace comprises a power trace.

8. The air bridge of claim 1, wherein the crossover circuit trace comprises a signal trace.

9-20. (canceled).

21. An air bridge produced by:
depositing one or more circuit components on a substrate;
depositing a sacrificial material over at least a portion of the circuit components;
depositing a crossover circuit trace of uniform composition over the sacrificial material, the crossover circuit trace crossing over the circuit components and being directly supported by the substrate on opposite sides of the sacrificial material; and
thermally decomposing the sacrificial material.

22. The air bridge of claim 21, wherein depositing a sacrificial material comprises depositing the sacrificial material in a manner causing the sacrificial material to be dome shaped.

23. The air bridge of claim 21, wherein the sacrificial material comprises polynorbornene.

24. The air bridge of claim 21, wherein the one or more circuit components comprise a circuit trace.

25. The air bridge of claim 24, wherein the circuit trace comprises a signal trace.

26. The air bridge of claim 24, wherein the circuit trace comprises a ground trace.

27. The air bridge of claim 24, wherein the circuit trace comprises a power trace.

28. The air bridge of claim 21, wherein the crossover circuit trace comprises a signal trace.
